(19) United States
(12) Patent Application Publication
(10) Pub. No.: US 2004/0083606 A1
(43) Pub. Date: May 6, 2004

(54) Circuit wiring board and method of manufacturing the same

(75) Inventors: Sadao Makita, Iruma-gun (JP); Kuniyasu Hosoda, Hanno-shi (JP)

Correspondence Address: Finnegan, Henderson, Farabow,, Garrett & Dunner, L.L.P., 1300 I Street, N.W., Washington, DC, 20005-3315, US

(73) Assignee: KABUSHIKI KAISHA TOSHIBA.

(21) Appl. No.: 10/680,248

(22) Filed: Oct. 8, 2003

(30) Foreign Application Priority Data
Oct. 31, 2002 (JP) 2002-318060

(51) Int. Cl. H05K 1/03; H05K 1/11; H01R 12/04

(52) U.S. Cl. 29/855; 29/830; 29/846; 29/831; 174/266; 174/255; 29/832; 29/840

(57) ABSTRACT

Soldering of a first electrode and first circuit component, soldering of a second electrode and second circuit component, and hardening of an encapsulating resin are simultaneously performed by using the encapsulating resin which having a hardening accelerating temperature higher than a preheating temperature and equal to or lower than a main heating temperature.

### CROSS-REFERENCE TO RELATED APPLICATIONS

This application is based upon and claims the benefit of priority from the prior Japanese Patent Application No. 2002-318060, filed Oct. 31, 2002, the entire contents of which are incorporated herein by reference.

### BACKGROUND OF THE INVENTION

1. Field of the Invention

The present invention relates to a circuit wiring board of, e.g., a semiconductor device obtained by mounting a circuit component on a wiring board by using a face down structure and encapsulating the gap with a resin, and a method of manufacturing the same.

2. Description of the Related Art

Conventionally, mounting of a circuit wiring board requires a high density. A face down structure, e.g., a flip chip mounting method is known to be effective to reduce the mounting area and increase the number of electrodes.

In this mounting method, a wiring board and circuit component having different thermal expansion coefficients are opposed to each other and connected via a projecting electrode. Therefore, the stress concentrates on the projecting electrode, and this often lowers the connection reliability. To prevent this, the stress concentrating on the projecting electrode is dispersed by encapsulating the gap between the circuit component and the wiring board with a resin, thereby improving the connection reliability.

A circuit wiring board as described above is obtained as follows. First, a solder paste is applied on a wiring board, and a small chip component such as a resistor or capacitor is mounted via the solder paste and connected by preheating, reflow heating, and cooling. Subsequently, a circuit component such as a semiconductor element is mounted on the wiring board by applying a flux on a projecting electrode of the circuit component. This circuit component is connected by heating, and the flux is washed away. After that, an encapsulating resin composition is supplied from the side surfaces of the circuit component and injected into the spacing between the circuit component and the wiring board by using a capillary phenomenon. Finally, the encapsulating resin composition is hardened by heat.

Recently, a technique by which an encapsulating resin composition having a flux function is used as the encapsulating resin composition described above is proposed. For example, this encapsulating resin composition having a flux function is used as described in Jpn. Pat. Appln. KOKAI Publication No. 2002-261118. That is, after a small chip component is connected, the encapsulating resin composition having a flux function is applied to a position on a wiring board where a circuit component is to be mounted, and then the circuit component is mounted. After that, connection by heat and thermosetting can be simultaneously performed. This facilitates injection of the encapsulating resin composition, and makes flux washing unnecessary. In addition, since one heating step is reduced, the fabrication process can be simplified.

When the encapsulating resin composition having a flux function is to be used, after a first circuit component such as a small chip component is mounted, preheating and heating are performed to connect the first circuit component on a first electrode, and natural cooling or forced cooling is well performed. After that, the encapsulating resin is applied to a position on a wiring board where a second circuit component such as a semiconductor element or package is to be formed. After the second circuit component is thus mounted, heating is performed.

Unfortunately, the encapsulating resin composition having a flux function is gradually thermoset while the temperature is raised, so cooling must be well performed even after the small chip component is connected. Accordingly, it is being required to further simplify the fabrication process.

### BRIEF SUMMARY OF THE INVENTION

According to a first aspect of the present invention, there is provided a method of manufacturing a circuit wiring board comprising,

preheating a circuit component mounted structure to a preheating temperature, the circuit component mounted structure including a wiring board having first and second electrodes, a first circuit component mounted on the first electrode, a second circuit component mounted on the second electrode via a projecting electrode, and an encapsulating resin composition having a flux function applied in a gap between the second circuit component and the wiring board facing the second circuit component and having a hardening accelerating temperature higher than the preheating temperature and not higher than a heating temperature, and

heating the circuit component mounted structure to the heating temperature from the preheating temperature to perform soldering of the first electrode and the first circuit component and soldering of the second electrode and second circuit component simultaneously with hardening of the encapsulating resin composition having a flux function.

According to a second aspect of the present invention, there is provided a circuit wiring board comprising a wiring board having first and second electrodes, a first circuit component mounted on the first electrode, a second circuit component mounted on the second electrode via a projecting electrode, and a encapsulating resin layer wherein the circuit wiring board is obtained by a method in which a circuit component mounted structure mounted with the first and second circuit components including an encapsulating resin composition which has a flux function and a hardening accelerating temperature higher than a preheating temperature and not higher than a heating temperature and is applied in a gap between the second circuit component and the wiring board facing the second circuit component, is preheated at the preheating temperature, and heated by raising a temperature from the preheating temperature to the heating temperature to perform soldering of the first electrode and the first circuit component and soldering of the second electrode and second circuit component simultaneously with hardening of the encapsulating resin composition having a flux function.

### BRIEF DESCRIPTION OF THE SEVERAL VIEWS OF THE DRAWING

The accompanying drawings, which are incorporated in and constitute a part of the specification, illustrate presently embodiments of the invention and, together with the generation description given above and the detailed description of the preferred embodiments given below, serve to explain the principles of the invention.

FIG. 1 is a graph showing one embodiment of the temperature profile of soldering and thermosetting in the present invention;

FIG. 2 is a view showing one embodiment of a heating apparatus can be used for the present invention;

FIG. 3 is a graph showing another embodiment of the temperature profile of soldering and thermosetting in the present invention;

FIG. 4 is a view showing one embodiment of a heating apparatus can be used for the present invention;

FIG. 5 is a view showing one embodiment of a circuit wiring board fabrication step of the present invention;

FIG. 6 is a view showing one embodiment of a circuit wiring board fabrication step of the present invention;

FIG. 7 is a view showing one embodiment of a circuit wiring board fabrication step of the present invention;

FIG. 8 is a view showing one embodiment of a circuit wiring board fabrication step of the present invention;

FIG. 9 is a flow chart showing one embodiment of the circuit wiring board fabrication steps of the present invention;

FIG. 10 is a flow chart showing one embodiment of the circuit wiring board fabrication steps of the present invention;

FIG. 11 is a view showing one embodiment of a circuit wiring board fabrication step of the present invention; and

FIG. 12 is a view showing one embodiment of a circuit wiring board fabrication step of the present invention.

### DETAILED DESCRIPTION OF THE INVENTION

A circuit wiring board manufacturing method according to the first aspect of the present invention is a process for connecting a first circuit component via a solder paste layer on a first electrode of a wiring board having the first electrode and a second electrode, connecting a second circuit component via a solder projecting electrode on the second electrode, and forming a encapsulating resin layer in the gap between the second circuit component and the wiring board facing the second circuit component using an encapsulating resin composition having a flux function. In this method, after the first circuit component is mounted on the solder paste layer, a position on the wiring board where the second circuit component is to be connected can be coated with the encapsulating resin composition having a flux function, without performing any soldering. After that, the second circuit component can be mounted via the solder projecting electrode to form a circuit component mounted structure. This circuit component mounted structure is preheated at a preheating temperature, and heated by raising the temperature from the preheating temperature to a heating temperature, thereby performing soldering of the first electrode and first circuit component and soldering of the second electrode and second circuit component simultaneously with hardening of the encapsulating resin composition having a flux function. Alternatively, after the first circuit component is mounted on the solder paste layer, the second circuit component can be mounted via the solder projecting electrode to form a circuit component mounted structure. Then an encapsulating resin composition having a flux function can be injected to the gap between the second circuit component and the wiring board facing the second circuit component to form a encapsulating resin layer to form a circuit component mounted structure.

The circuit wiring board according to the second aspect of the invention is obtained by the method according to the first aspect of the present invention.

The encapsulating resin composition can be applied to the present invention, and has a flux function and a hardening accelerating temperature higher than the preheating temperature and equal to or lower than the heating temperature.

Therefore, even with a temperature profile by which preheating is performed at a predetermined temperature and then heating is performed by raising the temperature, thermosetting of the encapsulating resin composition does not advance during the preheating. This makes it possible to simultaneously perform soldering of the first electrode and first circuit component, soldering of the second electrode and second circuit component, and hardening of the encapsulating resin composition having a flux function. Since this obviates the need for repetitive heating, the fabrication cost can be greatly reduced.

Also, when the heating step is repeated, thermal stress is applied on the already connected first circuit component, and this shortens the life of the component or breaks the component. However, the present invention eliminates this problem because heating is not repeated. Accordingly, a circuit wiring board obtained by the method of the present invention is superior not only in cost but also in life reliability.

As the first circuit component, a small chip component such as a resistor or capacitor can be used.

This small chip component can be mounted on a wiring board after a solder paste layer is printed on the wiring board, and can be connected by performing preheating and then heating by raising the temperature.

The solder paste can be formed by evenly mixing a solder powder and a pasted flux containing a solvent.

Since the solder paste has viscosity, it can fix the mounted first circuit component to some extent before the component is connected by heating.

As the second circuit component, a relatively large circuit component such as a semiconductor element or package can be used. In one embodiment of the invention the solder projecting electrode can be formed on the surface of the second circuit component and placed on the second electrode.

Before the second circuit component is mounted, a position on the wiring board surface where the second circuit component is to be mounted can be coated with the encapsulating resin composition having a flux function.

The hardening accelerating temperature of the encapsulating resin composition having a flux function used in the present invention is higher than the preheating temperature and equal to or lower than the heating temperature. Thermosetting of this encapsulating resin composition is accelerated after soldering of the solder projecting electrode is completed. If thermosetting of the encapsulating resin composition is completed before soldering of the solder projecting electrode is completed, soldering of the solder projecting electrode is interfered with, and this tends to lower the connection reliability.

The hardening accelerating temperature is a temperature at which thermosetting of the encapsulating resin composition advances to have influence on soldering of the solder projecting electrode.

The encapsulating resin composition in some embodiments of the invention can have a viscosity of 1 to 30 Pa·S at room temperature.

If the viscosity at room temperature is less than 1 Pa·S, the resin tends to have too high a wettability and spreads too much. If the viscosity exceeds 30 Pa·S, air is entrapped, and this tends to generate voids.

As a encapsulating resin composition in some embodiments of the invention, it is possible to use a thermosetting resin composition having a viscosity larger than 10 Pa·S and 30 Pa·S or less at a temperature from the preheating temperature (inclusive) to the hardening accelerating temperature (inclusive).

Generally, soldering of the solder paste and soldering of the solder projecting electrode have different soldering temperature profiles.

In soldering of the solder paste, no rapid heating in a short time period is performed. Instead, preheating such as drying is performed, and then heating for melting the solder paste is performed.

On the other hand, when soldering of the solder projecting electrode and thermosetting of the encapsulating resin composition are to be performed in the same heating step, the temperature profile generally differs from that of the solder paste. That is, preheating is short, and the heating temperature is set such that soldering of the solder projecting electrode and thermosetting of the encapsulating resin composition are well performed.

In the present invention, after preheating is performed, the temperature is further raised to perform heating at a temperature at which not only soldering of the solder paste but also soldering of the solder projecting electrode and thermosetting of the encapsulating resin composition are well complete.

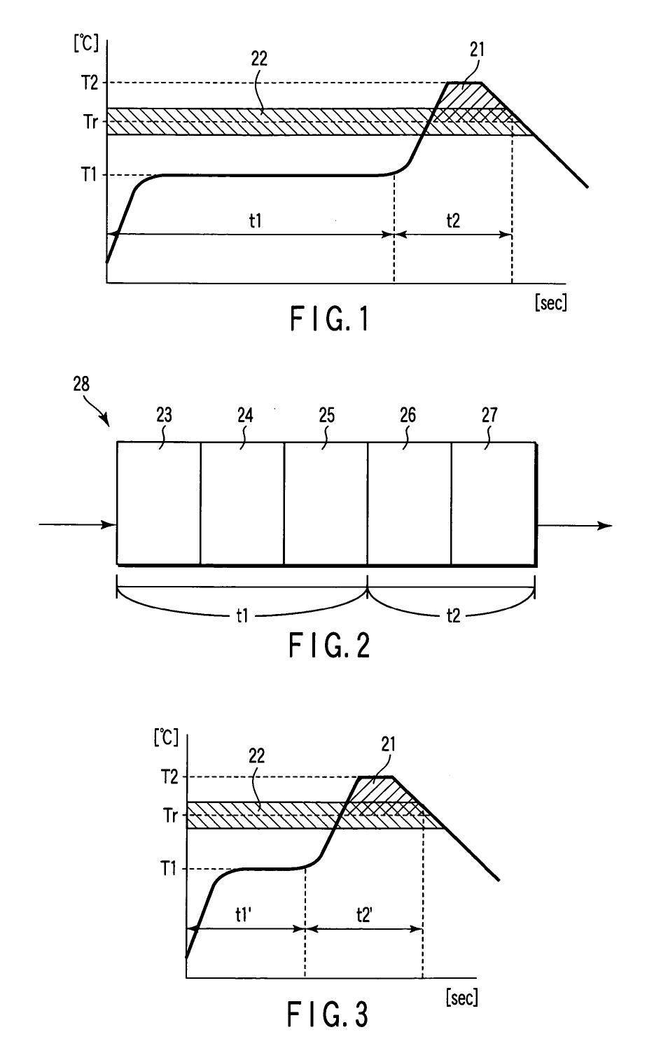

FIG. 1 shows an example of the temperature profile of soldering and thermosetting in accordance with one embodiment of the present invention.

In FIG. 1, reference symbol T1 denotes the preheating temperature; T2, the reflow heating temperature; t1, the preheating time; and t2, the heating time. Also, a hatched portion 21 indicates a thermosetting region of the encapsulating resin composition, and Tr indicates the thermosetting acceleration lower-limit temperature of the encapsulating resin composition. A diagonally shaded areas 22 in FIG. 1 shows a temperature range for a solder paste melting temperature and a solder projecting electrode melting temperature.

FIG. 2 shows one embodiment of a heating apparatus can be used for soldering and thermosetting. As show in this figure, the heating apparatus 28 includes heaters 23, 24, 25, 26, and 27, a circuit component mounted structure to be heated can be heated with transferring in direction shown by arrows at a constant-speed. Heater 23 is set for allowing the temperature of the circuit component mounted structure to rise to T1. Heater 24, 25 is set for allowing the temperature of the circuit component mounted structure to maintain at T1. Heater 26 is set for allowing the temperature of the circuit component mounted structure to rise to T2 and keep it. Heater 27 is set for allowing a temperature of the circuit component mounted structure to cool down gradually. In FIG. 1, the preheating time t1 corresponds to a time for passing the circuit component mounted structure through the heater 23 to 25, and heating time t2 corresponds to a time for passing the circuit component mounted structure through the heater 26, 27.

As shown in FIG. 1, in one embodiment of the present invention, hardening of the encapsulating resin composition is not accelerated even when preheating is performed. This makes it possible to simultaneously perform solder paste soldering, solder projecting electrode soldering, and encapsulating resin composition thermosetting having different temperature profiles.

When Sn—Pb-based alloy solder having a melting temperature of 183° C. is used in the solder paste and solder projecting electrode, the heating process of this embodiment of the present invention is performed at 200° C. to 230° C. for, e.g., 20 to 60 sec.

The preheating process is performed to reduce thermal shock to circuit components, and remove most of volatile materials in the solder paste by evaporation, thereby drying the solder and cleaning to some extent the solder powder and the metal surface to be soldered. This preheating process is performed at a temperature lower by, e.g., 50 to 80° C. than that of the heating process for a predetermined time, e.g., 60 to 90 sec. The preheating process can prevent a small chip component standing phenomenon such as a Manhattan (tombstone) phenomenon, and a solder capillary phenomenon such as wicking.

The preheating time can be further reduced by controlling a chemically active temperature of the encapsulating resin composition allowing to rise to a temperature near the preheating temperature.

FIG. 3 shows an example of the temperature profile of soldering and thermosetting in this case.

In this temperature profile a preheating time is further reduced. The temperature profile is similar to that of FIG. 1 except for the preheating time t1 is 40 seconds.

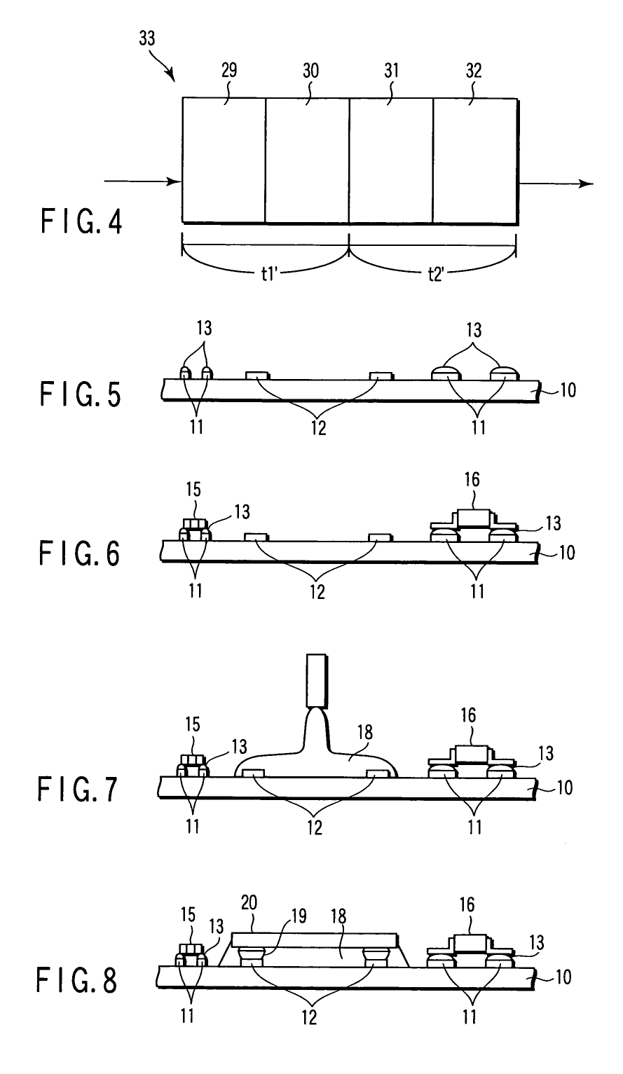

FIG. 4 shows one embodiment of a heating apparatus can be used for soldering and thermosetting by this temperature profile.

As show in this figure, the heating apparatus 33 includes heaters 29, 30, 31, and 32, a circuit component mounted structure to be heated can be heated with transferring in direction shown by arrows at a constant-speed. Heater 29 is set for allowing the temperature of the circuit component mounted structure to rise to T1. Heater 30 is set for allowing the temperature of the circuit component mounted structure to maintain at T1. Heater 31 is set for allowing the temperature of the circuit component mounted structure to rise to T2 and keep it. Heater 32 is set for allowing a temperature of the circuit component mounted structure to cool down gradually. In FIG. 3, the preheating time t1 corresponds to a time for passing the circuit component mounted structure through the heater 29 and 30, and heating time t2 corresponds to a time for passing the circuit component mounted structure through the heater 31, 32.

The soldering temperature of the solder projecting electrode is lower than the upper limit of the hardening accelerating temperature, i.e., the thermosetting completion temperature of the encapsulating resin composition. This soldering temperature can be higher than the lower limit of the hardening accelerating temperature. However, the soldering temperature is preferably equal to or lower than the hardening accelerating temperature.

The soldering temperature of the solder paste is preferably lower than the thermosetting completion temperature of the encapsulating resin composition, and equal to or lower than the hardening accelerating temperature. Also, the soldering temperature of the solder paste can substantially equal to the soldering temperature of the solder projecting electrode, although the former can also be higher or lower than the latter.

Examples of the solder alloy usable in some embodiment of the present invention are an Sn—Pb-based alloy, Sn—Ag-based alloy, Sn—Ag—Cu-based alloy, and Sn—Ze-based alloy.

The encapsulating resin composition having a flux function used in examples of the present invention can be made of a thermosetting resin composition, in one embodiment of the invention it can contain a thermosetting resin and flux component.

Examples of the thermosetting resin used are an epoxy resin, silicone resin, urethane resin, and phenoxy resin. An epoxy resin is favored in respect of the heat resistance, processability, and adhesion.

Examples of the epoxy resin are a bisphenol A epoxy resin, bisphenol F epoxy resin, biphenyl epoxy resin, o-cresol novolak epoxy resin, triphenolmethane epoxy resin, dicyclopentadiene epoxy resin, and terpene epoxy resin.

Examples of the flux component are an acid-based flux, rosin-based flux, and organic carboxylic acid compound. The content of the flux component can be 0.5 to 30 wt % with respect to 100 parts by weight of the thermosetting resin.

A hardener can be added where necessary to the encapsulating resin composition having a flux function used in the present invention. Examples of this hardener are a phenol aralkyl-based resin, a phenol novolak-based resin, a phenolic resin, an acid anhydride such as methylhexahydro phthalic anhydride, and an amine-based hardener such as dicyanamide.

In some embodiments, the hardener can have a reducing action and can contain a hydroxyl group or the like. The content of this hardener can be 5 to 20 parts by weight, if the hardener is a solid, and 10 to 50 parts by weight, if the hardener is a liquid, with respect to 100 parts by weight of the thermosetting resin.

The hardening accelerating temperature can be appropriately adjusted by changing the blending of the thermosetting resin composition described above.

For example, when Sn—Pb-based alloy solder having a melting temperature of 183° C. is used in the solder paste and solder projecting electrode, the hardening accelerating temperature can be set at 190° C. to 220° C.

The formation procedure of a circuit component mounted structure used in one embodiment of the present invention includes a first step of printing a solder paste layer on a first electrode, a second step of mounting a first circuit component on the solder paste layer, a third step of applying an encapsulating resin composition to a position on a wiring board where a second circuit component is to be mounted, and a fourth step of pressing a solder projecting electrode to contact the second electrode, and mounting the second circuit component on the wiring board via the encapsulating resin composition.

The third step of applying the encapsulating resin composition can be performed before the step of mounting the first circuit component.

FIGS. 5 to 8 are views each showing part of the circuit wiring board fabrication process according to the present invention.

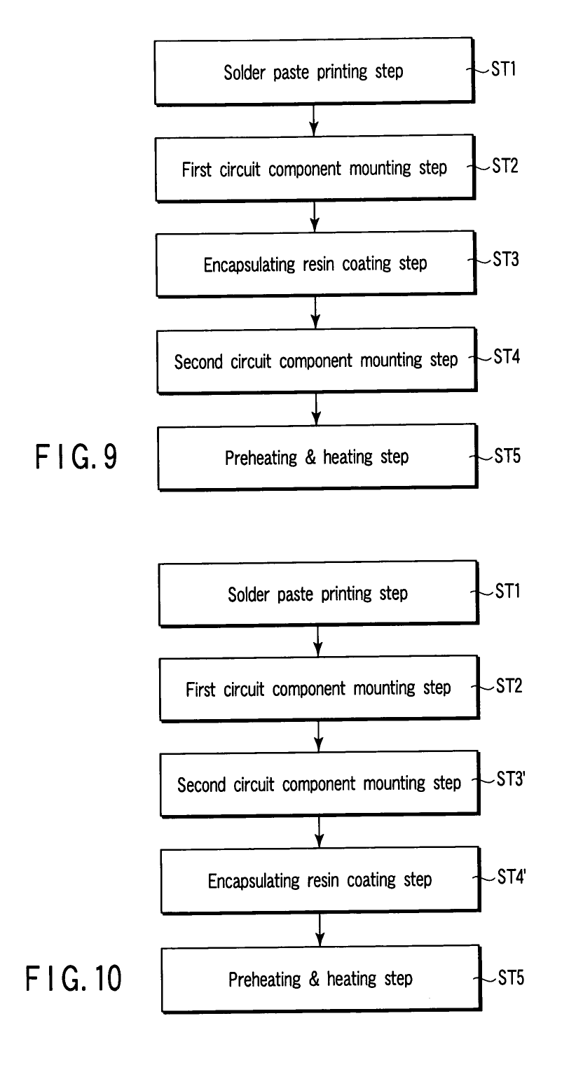

FIG. 9 is a flow chart showing an example of the circuit wiring board fabrication method of the present invention.

One embodiment of present invention will be described in detail with reference to FIG. 5 to 9.

A wiring board 10 having a first electrode 11 and second electrode 12 is prepared, as shown in FIGS. 5 to 8.

First, as shown in FIG. 5, a solder paste such as Sn—Pb alloy paste having a melting temperature of 183° C. is printed on the first electrode 11 to form a solder paste layer 13. (step 1)

Next, as shown in FIG. 6, first circuit components such as a resistor 15 and capacitor 16 are mounted on the solder paste layer 13 by positioning them by using a part mounter or the like. (step 2)

Furthermore, as shown in FIG. 7, a position on the surface of the wiring board 10 where a second circuit component is to be formed is coated with an epoxy-based encapsulating resin composition 18 containing a flux component. The epoxy-based encapsulating resin composition 18 has a hardening accelerating temperature of, e.g., 180° C. or more, which is higher than the preheating temperature, and can be completely hardened at a hardening completion temperature of about 230° C. higher than the melting temperature of the solder paste layer and a solder projecting electrode consisting of Sn—Pb alloy having a melting temperature of 183° C. (step 3)

This encapsulating resin coating step can be performed before the first circuit component mounting step.

After that, as shown in FIG. 8, a semiconductor element 20 including solder projecting electrodes 19 is opposed as a second circuit component to the wiring board, and mounted by positioning the solder projecting electrodes 19 and second electrodes 12. (step 4)

Finally, similar to the temperature profile shown in FIG. 1, preheating is performed at, e.g., 150° C. for 60 sec, and then the temperature is raised to perform heating at 183° C. or more such as 210 to 220° C. for 40 sec, thereby simultaneously performing reflow of the solder paste layer 13 and solder projecting electrodes 19 and thermosetting of the epoxy-based encapsulating resin composition 18 containing a flux component. (step 5)

As is apparent from FIG. 9, the present invention can exceptionally reduce the fabrication cost by performing the preheating and heating step once, without any further heating step or cooling step.

The encapsulating resin coating step can be also performed after the second circuit component mounting step.

FIG. 10 is a flow chart showing an example of the circuit wiring board fabrication method of the present invention when the encapsulating resin is coated after the second circuit component is mounted.

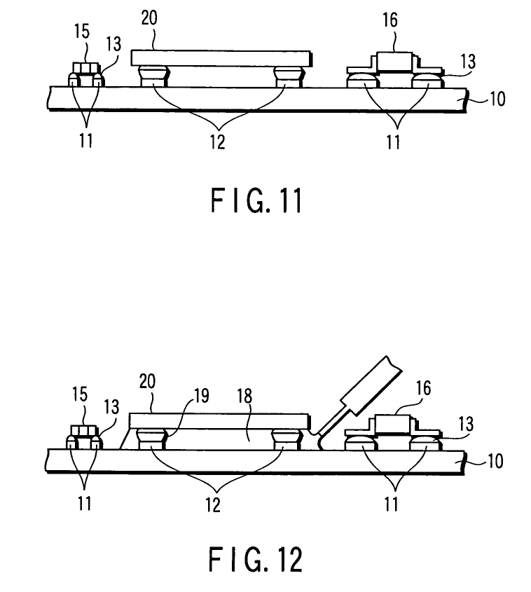

FIGS. 11 and 12 are views each showing part of the circuit wiring board fabrication process according to the present invention.

As shown in FIG. 11, a semiconductor element 20 including solder projecting electrodes 19 is opposed as a second circuit component to the wiring board, and mounted by positioning the solder projecting electrodes 19 and second electrodes 12. (step 3′)

After that, as shown in FIG. 12, the encapsulating resin is injected to the spacing between the circuit component and the wiring board by using a capillary phenomenon. (Step 4′)

Finally, similar to the temperature profile shown in FIG. 1, preheating is performed at, e.g., 150° C. for 60 sec, and then the temperature is raised to perform heating at 183° C. or more such as 210 to 220° C. for 40 sec, thereby simultaneously performing reflow of the solder paste layer 13 and solder projecting electrodes 19 and thermosetting of the epoxy-based encapsulating resin composition 18 containing a flux component. (Step 5′)

A solder component for the solder paste layer and the solder projecting electrode is not defined to Sn—Pb alloy. The other solder component such as Sn—Ag—Cu-based alloy having a melting temperature of 220° C. can be used instead of Sn—Pb alloy. When Sn—Ag—Cu alloy is solder component for the solder paste layer and the solder projecting electrode, the preheating temperature is set to 150° C., the heating temperature and the hardening accelerating temperature can be set to 230 to 240° C.

Additional advantages and modifications will readily occur to those skilled in the art. Therefore, the invention in its broader aspects is not limited to the specific details and representative embodiments shown and described herein. Accordingly, various modifications may be made without departing from the spirit and scope of the general inventive concept as defined by the appended claims and their equivalents.

What is claimed is:

1. A method of manufacturing a circuit wiring board comprising,
preheating a circuit component mounted structure to a preheating temperature, the circuit component mounted structure including a wiring board having first and second electrodes, a first circuit component mounted on the first electrode, a second circuit component mounted on the second electrode via a projecting electrode, and an encapsulating resin composition having a flux function formed in a gap between the second circuit component and the wiring board facing the second circuit component and having a hardening accelerating temperature higher than the preheating temperature and not higher than a heating temperature, and
heating the circuit component mounted structure to the heating temperature from the preheating temperature to perform soldering of the first electrode and the first circuit component and soldering of the second electrode and second circuit component simultaneously with hardening of the encapsulating resin composition having a flux function.

2. A method according to claim 1, wherein the structure is preheated at the temperature of not less than 120° C. and less than 220° C.

3. A method according to claim 1, wherein the structure is heated at the temperature of 210° C. to 240° C.

4. A method according to claim 1, wherein the hardening accelerating temperature is not less than 190° C. to less than 230° C.

5. A circuit wiring board comprising a wiring board having first and second electrodes, a first circuit component mounted on the first electrode, and a second circuit component mounted on the second electrode via a projecting electrode, wherein the circuit wiring board is obtained by a method in which a structure mounted with the first and second circuit components including an encapsulating resin composition which has a flux function and a hardening accelerating temperature higher than a preheating temperature and not higher than a heating temperature and is formed in a gap between the second circuit component and the wiring board facing the second circuit component, is preheated at the preheating temperature, and heated by raising a temperature from the preheating temperature to the heating temperature to perform soldering of the first electrode and the first circuit component and soldering of the second electrode and second circuit component simultaneously with hardening of the encapsulating resin composition having a flux function.

6. A board according to claim 5, wherein the encapsulating resin composition contains an epoxy-based thermosetting resin, flux component, and hardener.

7. A board according to claim 6, wherein the hardener is one member selected from the group consisting of phenol-based, acid anhydride-based, and amine-based hardeners containing an OH group, and added in amount of 5 to 20 parts by weight, if the hardener is a solid, and in amount of 10 to 50 parts by weight, if the hardener is a liquid, with respect to 100 parts by weight of the encapsulating resin composition.

8. A board according to claim 5, wherein the encapsulating resin has a viscosity of 1 to 30 Pa·S at room temperature.

9. A board according to claim 5, wherein the preheating temperature is not less than 120° C. and less than 220° C.

10. A board according to claim 5, wherein the heating temperature is 210° C. to 240° C.

11. A board according to claim 5, wherein the hardening accelerating temperature is not less than 190° C. less than 230° C.
